(19) United States
(12) Patent Application Publication
(10) Pub. No.: US 2009/0176449 A1
(43) Pub. Date: Jul. 9, 2009

(54) Out-of-Band Signal Generator and Frequency Band Expander

(75) Inventor: Atsushi Tashiro, Kanagawa (JP)

Correspondence Address: RABIN & Berdo, PC, 1101 14TH STREET, NW, SUITE 500, WASHINGTON, DC, 20005, US

(73) Assignee: Oki Electric Industry Co., Ltd., Tokyo (JP)

(21) Appl. No.: 12/227,483

(22) PCT Filed: Jan. 31, 2007
(86) PCT No.: PCT/JP2007/051573

§ 371 Date: Nov. 19, 2008

(30) Foreign Application Priority Data
May 22, 2006 (JP) 2006-141686

(51) Int. Cl. H04B 7/24; H03G 5/00

(52) U.S. Cl. 455/39; 381/98

(57) ABSTRACT

An out-of-band signal generator for generating, from a band-limited signal with a limited frequency band, an out-of-band signal including a frequency component outside the limited frequency band, having a frequency structure estimating means for estimating the frequency structure of the band-limited signal, an out-of-band source signal generating means for generating an out-of-band source signal including an out-of-band frequency component from the band-limited signal, a frequency structure adjusting means for adjusting the frequency structure of the out-of-band source signal according to the estimated frequency structure of the band-limited signal, and a component extracting means for extracting a prescribed band in the out-of-band source signal with the adjusted frequency structure.

### TECHNICAL FIELD

The present invention relates to an out-of-band signal generator and a frequency band expander, and can be applied in communications, broadcasting, and so on to obtain an audio signal, for example, with an expanded frequency band at the receiving end from an audio signal transmitted in a narrow frequency band.

### BACKGROUND ART

A variety of networks are now frequently used for voice communication. Nevertheless, as was customary in the days of conventional general public networks, voice telephone communication is carried out in the limited frequency band from 300 Hz to 3.4 kHz generally referred to as the telephone band. Human speech, however, includes components below 300 Hz and above 3.4 kHz, and since these components have an important bearing on the individuality of the speech, the lack of these components leads not only to a lack of individuality but also to reduced speech quality. It would therefore be desirable to converse in speech including these components, but the problem has been that the switches in general public networks cannot transmit speech outside the telephone band. This problem is addressed by, for example, frequency band expansion methods of the type proposed in Patent Document 1.

The conventional frequency band expander shown in Patent Document 1 will be described using FIG. 11. This conventional apparatus inputs a band-limited signal DC limited to the frequency band from 300 Hz to 3.4 kHz. The band-limited signal DC is converted by a sampling frequency converter 1 to a converted source signal S with a converted sampling frequency. The converted source signal S is furnished to a low-frequency signal generator 10, a high-frequency signal generator 11, and a high-frequency unvoiced component generator 12.

In the low frequency signal generator 10, an internal period estimator 5 outputs low-frequency period information I, including information about the period of the converted source signal S, and a low-frequency periodic signal TW, including the periodic waveform of a conversion signal, to a low-frequency waveform generator 2, which outputs a synthesized low-frequency signal LS on the basis thereof. A high-frequency waveform generator 3 in the high-frequency signal generator 11 outputs a synthesized high-frequency signal HS on the basis of fundamental period information HPI output from the period estimator 5, which is shared with the low-frequency signal generator 10. In the high-frequency unvoiced component generator 12, a synthesized unvoiced signal US is output on the basis of the converted source signal S. The synthesized low-frequency signal LS, synthesized high-frequency signal HS, synthesized unvoiced signal US, and converted source signal S are added in an additive combiner 6, which outputs a band-expanded signal V. By providing signals with low-frequency components and high-frequency components simultaneously with the transmitted signal, the band-expanded signal V enables the same sense of presence to be heard from the band-limited signal DC as from a wideband signal including those components.

Patent Document 1: Japanese Patent Application Publication No. H9-258787

### DISCLOSURE OF THE INVENTION

### Problems to be Solved by the Invention

Since the processing of the high-frequency waveform generator is not specified in the prior art described in Patent Document 1; however, there is the possibility of the output of a waveform that does not take the characteristics of human speech into consideration, and there is inadequate capability to generate speech similar to a wideband signal.

It is therefore an object of the present invention to provide an out-of-band signal generator and frequency band expander that can produce, by band expansion, a wideband signal having characteristics similar to those of the original band-limited signal.

### Means of Solution of the Problems

The inventive out-of-band signal generator is a device for generating an out-of-band signal from a band-limited signal with a limited frequency band, the out-of-band signal including a frequency component outside the limited frequency band; the out-of-band signal generator comprises a frequency structure estimating means for estimating the frequency structure of the band-limited signal, an out-of-band source signal generating means for generating an out-of-band source signal including an out-of-band frequency component from the band-limited signal, a frequency structure adjusting means for adjusting the frequency structure of the out-of-band source signal according to the frequency structure of the band-limited signal estimated by the frequency structure estimating means, and a component extracting means for extracting a prescribed band in the out-of-band source signal with the adjusted frequency structure to obtain the out-of-band signal.

The inventive frequency band expander includes an out-of-band signal generator that generates, from a band-limited signal having a limited frequency band, an out-of-band signal including a frequency component outside the limited frequency band; the frequency band expander combines the band-limited signal and the out-of-band signal to obtain a band-expanded signal including a frequency component exceeding a limit of the band-limited signal; the inventive out-of-band signal generator is used as the out-of-band signal generator.

### Effect of the Invention

In the inventive out-of-band signal generator and frequency band expander, because the frequency structure of the band-limited signal is estimated and is reflected in the out-of-band signal, a wideband signal having characteristics similar to those of the original band-limited signal can be produced by band expansion.

### BRIEF DESCRIPTION OF THE DRAWINGS

FIG. 1 is a block diagram showing the internal structure of the high-frequency signal generator in a first embodiment of the invention.

FIG. 2 is a block diagram showing the overall structure of the voice signal band expander in the first embodiment.

FIGS. 3(a) and 3(b) explain the frequency shifting method used by the frequency converter in the first embodiment.

FIGS. 4(a) and 4(b) explain the frequency structure estimation method used by the frequency structure estimator in the first embodiment.

FIG. 5 is a block diagram showing the internal structure of the structure adjuster in the first embodiment.

FIG. 6 is a block diagram showing the internal structure of the high-frequency signal generator in a second embodiment of the invention.

FIG. 7 is a block diagram showing the overall structure of the voice signal band expander in a third embodiment of the invention.

FIG. 8 is a block diagram showing the internal structure of the high-frequency signal generator in the third embodiment.

FIG. 9 is a block diagram showing the overall structure of the voice signal band expander in a fourth embodiment of the invention.

FIG. 10 is a block diagram showing the overall structure of a variation of the first embodiment.

FIG. 11 is a block diagram showing the overall structure of a conventional frequency band expander.

### DESCRIPTION OF REFERENCE NUMERALS

1 . . . sampling frequency converter
5 . . . period estimator
6 . . . additive combiner
10 . . . low-frequency signal generator
12 . . . high-frequency unvoiced component generator
100, 200, 300 . . . frequency band expander
103, 403 . . . high-frequency waveform generator (out-of-band signal generator)
111, 411 . . . high-frequency signal generator
121 . . . frequency converter
122, 222 . . . frequency structure estimator
123, 223 . . . structure adjuster
124, 224 . . . component extractor
203 . . . high-frequency waveform generator
211, 311 . . . high-frequency component signal generator
221 . . . high-frequency unvoiced waveform generator
307 . . . signal emphasizer
425, 426 . . . smoothing index generator
427 . . . frequency structure smoother

### BEST MODE FOR CARRYING OUT THE INVENTION

### (A) First Embodiment

An out-of-band signal generator and frequency band expander according to a first embodiment of the invention will be described in detail below with reference to the drawings.

### (A-1) Structure of the First Embodiment

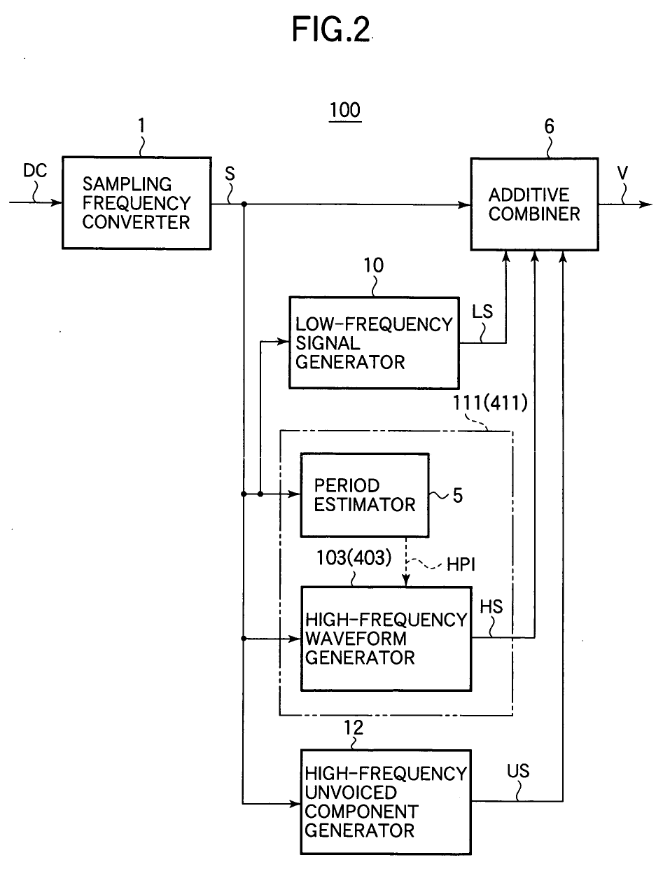

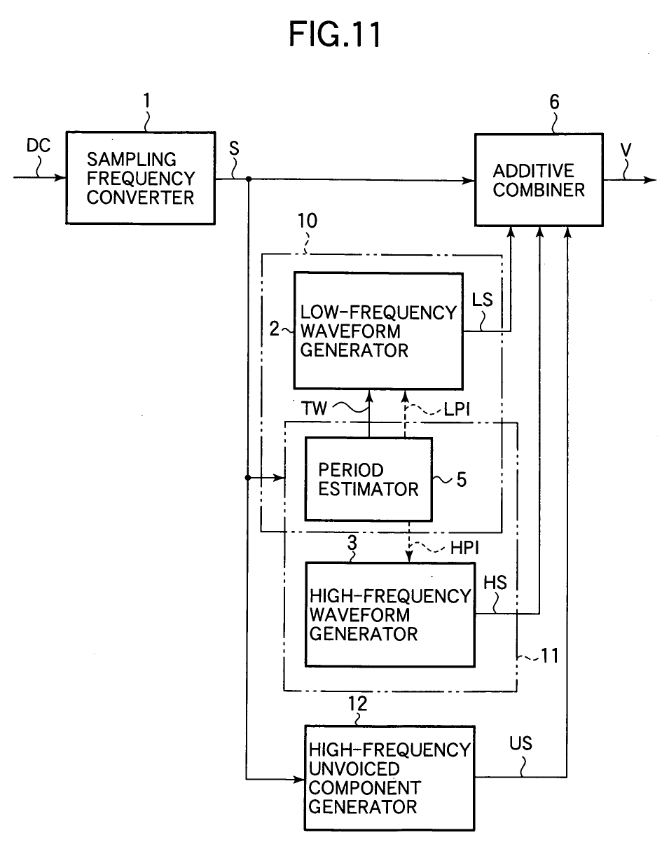

FIG. 2 is a block diagram showing the overall structure of the frequency band expander 100 in the first embodiment. Elements in FIG. 2 that are identical to or correspond to elements shown in FIG. 11 are given the same reference numerals.

As shown in FIG. 2, the frequency band expander 100 in the first embodiment comprises a sampling frequency converter 1, a low-frequency signal generator 10, a high-frequency signal generator 111, a high-frequency unvoiced component generator 12, and an additive combiner 6. The frequency band expander 100 generates a band-expanded signal V from a band-limited input signal DC. The low-frequency signal generator 10 in FIG. 2 includes a period estimator 5 as shown in FIG. 11. The low-frequency signal generator 10 is drawn as shown in FIG. 2, however, to emphasize that the period estimator 5 is an element of the high-frequency signal generator 111, which is the characterizing part of the first embodiment.

The first embodiment and subsequent embodiments assume that processing is performed in units of voice frames, each frame covering a fixed period of time (such as 10 ms), but the frame length is not limited to any particular time. The processing need not be performed in fixed frames; it may be performed in variable-length frames, or one sample at a time.

In the frequency band expander 100 of the first embodiment, the high-frequency signal generator 111, which is the out-of-band signal generator in the first embodiment, differs from the signal generator in the conventional expander in its internal structure and processing. The high-frequency signal generator 111 includes a period estimator 5 and a high-frequency waveform generator 103, and the high-frequency waveform generator 103 differs from the waveform generator in the conventional expander. In the first embodiment, the period estimator 5 outputs the fundamental period information HPI of the converted source signal S.

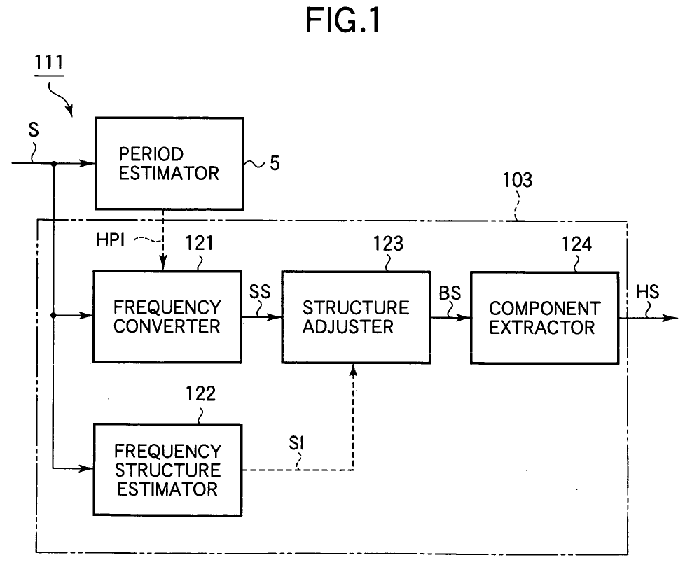

FIG. 1 is a block diagram showing the internal structure of the high-frequency signal generator 111 in the first embodiment. The high-frequency waveform generator 103 in the high-frequency signal generator 111 of the first embodiment includes a frequency converter 121, a frequency structure estimator 122, a structure adjuster 123, and a component extractor 124.

The frequency converter 121 receives the converted source signal S, carries out a frequency shift on the converted source signal S based on the fundamental period information HPI, and outputs a shifted signal SS. The frequency shifting method employed in the frequency converter 121 will be described later.

The frequency structure estimator 122 receives the converted source signal S, estimates the skew of the frequency structure of the signal, and outputs skew information SI. The estimation method employed in the frequency structure estimator 122 will be described later.

The structure adjuster 123 receives the shifted signal SS, modifies the skew of the frequency structure of the shifted signal SS, and outputs a modified signal BS. The skew modification method employed in the structure adjuster 123 will be described later.

The component extractor 124 receives the modified signal BS, extracts a high-frequency component which must be added by the additive combiner 6, and outputs a synthesized high-frequency signal HS.

### (A-2) Operation of the First Embodiment

Next the operation of the frequency band expander 100 in the first embodiment will be described. In the first embodiment, the constituent elements of the frequency band expander 100 operate as shown below each time one voice frame is input.

The band-limited signal DC input to the frequency band expander 100 is converted to a converted source signal S with an increased sampling frequency by the sampling frequency converter 1, and the converted source signal S is supplied to the additive combiner 6, low-frequency signal generator 10, high-frequency signal generator 111, and high-frequency unvoiced component generator 12. For example, the sampling frequency converter 1 converts the sampling frequency from 8 kHz to 16 kHz. The sampling frequency before conversion and the sampling frequency after conversion are not limited to these exemplary values and can be determined in accordance with the sampling frequency of the audio signal of the device in which the frequency band expander 100 is actually used.

In the high-frequency signal generator 111, the internal period estimator 5 and high-frequency waveform generator 103 generate a synthesized high-frequency signal HS from the converted source signal S. The internal operation of the high-frequency signal generator 111 will be described next.

The period estimator 5 estimates the fundamental period information HPI from the converted source signal S. As the method of estimating the fundamental period information HPI in the period estimator 5, it is possible to use the amount of delay that maximizes the autocorrelation function of the converted source signal S as the fundamental period information HPI, but the fundamental period estimation method is not limited to this method. Other possible methods include an estimation method based on the discrete Fourier transform series in the frame. The period estimator 5 may also estimate the fundamental period information HPI from the input band-limited signal DC.

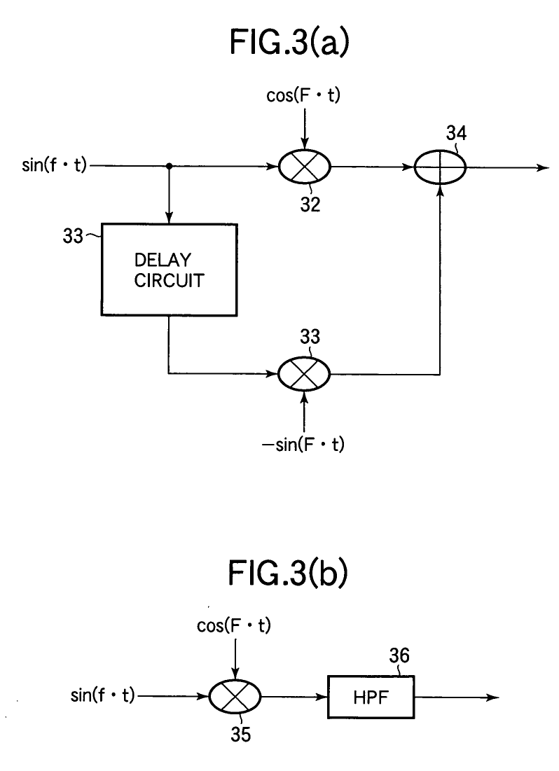

The frequency converter 121 carries out a frequency shift of the input converted source signal S by the frequency corresponding to the fundamental period information HPI, changing it to the shifted signal SS. FIGS. 3(a) and 3(b) outline two exemplary frequency shifting methods that may be employed in the frequency converter 121. FIGS. 3(a) and 3(b) show hardware configurations for executing the frequency shift, but the frequency shift may be implemented by software processing.

The first frequency shifting method will be described using FIG. 3(a). Let the input source signal corresponding to the converted source signal S input to the frequency converter 121 be sin(f·t), where f represents an angular frequency corresponding to the frequency of the converted source signal S and t represents time. After an angular frequency F corresponding to the frequency to be shifted is determined, a cosine signal cos(F·t) and a sine signal—sin(F·t) are input.

The angular frequency F is determined as follows. Letting the frequency corresponding to the fundamental period information HPI be f0, one of the integral multiples f0, 2·f0, 3·f0, and so on belonging to the desired expanded high-frequency band BH (the lowest multiple belonging to the high-frequency band BH, for example) is selected as the shift frequency, and the corresponding angular frequency F is calculated.

The source signal sin(f·t) is multiplied by the cosine signal cos(F·t) by a multiplying circuit 32 and then supplied to the adding circuit 34. The source signal sin(f·t) is also delayed by π/2 by a delay circuit 31, where π is determined by, for example, the fundamental period information HPI, to obtain a delayed source signal

sin(f·t+π/2)=−cos(f·t)

which is multiplied by the cosine signal cos(F·t) by a multiplying circuit 33 and supplied to an adding circuit 34. The signal output from the adding circuit 34 is

sin(f·t)·cos(F·t)+sin(F·t)·cos(f·t)=sin((F+f)·t)

That is, the adding circuit 34 outputs the frequency-shifted shifted signal SS.

The second frequency shifting method shown in FIG. 3(b) is based on similar trigonometric calculations. A multiplying circuit 35 multiplies the source signal sin(f·t) by the cosine signal cos(F·t), and obtains

1/2{sin((f+F)·t)+sin((f−F)·t)}

If amplitude is ignored, this formula can be expressed as follows.

sin((f+F)·t)+sin((f−F)·t)

A shifted signal can be obtained by using a high-pass filter (HPF) 36 to extract the first component sin((f+F)·t). The first component can be extracted from the product by setting the cutoff frequency of the high-pass filter 36 in the vicinity of the lower limit frequency of the desired expanded high-frequency band BH, for example.

Although the size of the frequency shift is calculated frame by frame here, the shift frequency obtained from the fundamental period in the immediately preceding frame may be held, and the angular frequency F may be varied from sample to sample so that the shift frequency of the immediately preceding frame changes continuously to the shift frequency described above.

The frequency structure estimator 122 estimates the general skew of the spectrum of frequency components (frequency structure) in the converted source signal S and outputs the estimated result as skew information SI.

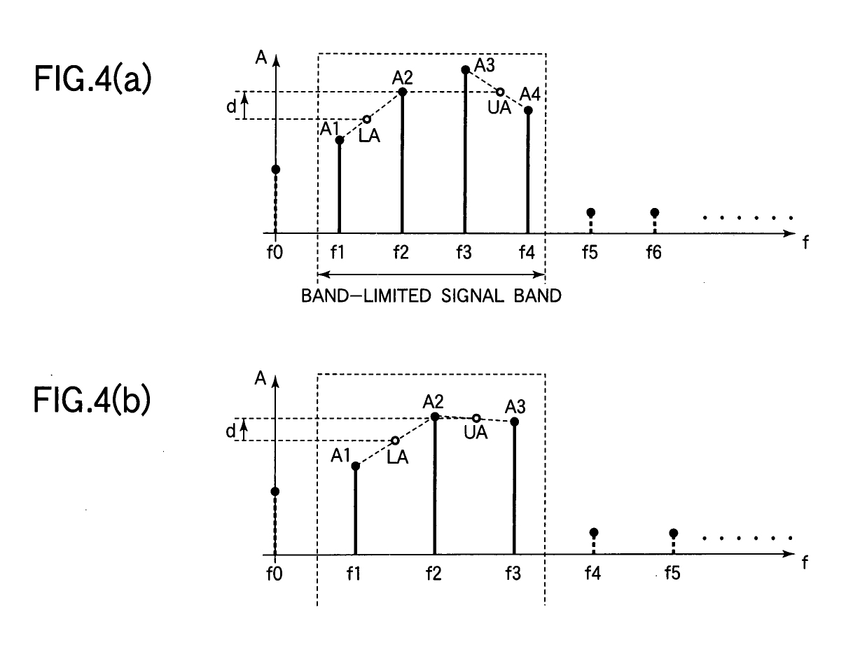

An example of the estimation method of the frequency structure estimator 122 will be described with reference to FIGS. 4(a) and 4(b). A series (frame) of values of the input converted source signal S is divided into subframes. The length of a subframe may be around 1 ms but is not limited to that value. A Fourier transform is performed in the subframe. From the result of the Fourier transform, several output values between the upper limit (3400 Hz, for example) and the lower limit (300 Hz, for example) of the frequency of the input band-limited signal are extracted. The results of Fourier transforms are shown for reference on the frequency axis in FIGS. 4(a) and 4(b).

FIG. 4(a) shows a case in which an even number (four) of output values are extracted. In that case, the mean value LA of the half of the output values (A1, A2) closer to the lower limit is subtracted from the mean value UA of the half of the output values (A3, A4) closer to the upper limit, and the result is taken as the amount of change d in the subframe.

FIG. 4(b) shows a case in which an odd number (three) of output values are extracted. A mean output value LA is obtained by averaging the output value A1 closest to the lower limit and the output value A2 in the middle. Another mean output value UA is obtained by averaging the output value A3 closest to the upper limit and the output value A2 in the middle. The mean output value LA is subtracted from the mean output value UA, and the result is taken as the amount of change d in the subframe. If there are more than three output values, the amount of change d in the subframe is calculated similarly as the difference between the mean value LA of the output values closer to the lower limit and the mean value UA of the output values closer to the upper limit.

The amount of change d in each subframe is calculated in an entire single voice frame, and the mean value of the amounts of change d in all the subframes is output as skew information SI.

The estimation method employed in the frequency structure estimator 122 is not limited to the method described with reference to FIGS. 4(a) and 4(b); any other method that can estimate the skew of the frequency structure can be used.

The structure adjuster 123 modifies the frequency structure of the shifted signal SS from the frequency converter 121 in accordance with the skew information SI received from the frequency structure estimator 122 and outputs it as the modified signal BS.

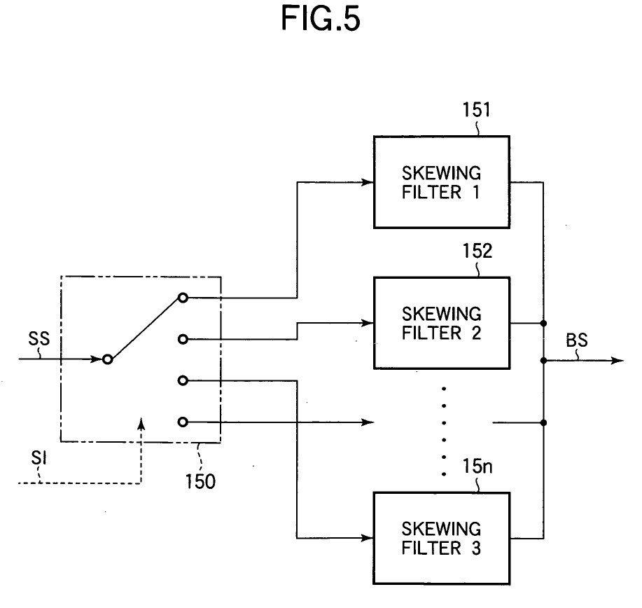

FIG. 5 is a block diagram showing an example of the internal structure of the structure adjuster 123. In FIG. 5, the structure adjuster 123 includes a plurality of skewing filters 151 to 15n and modifies the frequency structure by selecting a skewing filter for filtering the shifted signal SS by means of a switch 150, which performs a switching operation in accordance with the skew information SI. The skewing filters 151 to 15 are filters that give the frequency characteristic of the filtered signal a particular skew with respect to the frequency characteristic of the shifted signal SS before being filtered. Skewing corresponds to multiplying each frequency component by a gain that varies linearly as the frequency component increases. For example; three types of skewing filters may be provided: a skewing filter for imparting a positive skew, a skewing filter for imparting a negative skew, and a skewing filter that does not impart any skew (this filter may be omitted; only a channel need be provided), and the skewing filter that filters the shifted signal SS may be selected in accordance with whether the skew information SI has a positive value greater than or equal to a first prescribed value (a positive value), a negative value less than or equal to a second prescribed value (a negative value), or a value close to 0, below the first prescribed value and above the second prescribed value. The number of skewing filters and the size of skew are not limited and can be selected arbitrarily. Alternatively, a single variable skewing filter may be used, and its variable skew may be controlled.

Skewing the shifted signal SS can make the features of the input signal more obvious than in a signal simply shifted to the high-frequency band or a signal obtained by simply attenuating the shifted signal.

The component extractor 124 extracts the component to be added in the additive combiner 6 from the modified signal BS and outputs the result as a synthesized high-frequency signal HS. The extraction can be carried out by filtering with a bandpass filter having a passband of 4000 Hz to 7000 Hz, for example; the designer can specify arbitrary values as these upper and lower limit frequencies to improve the quality of the output signal. Any method of extracting a high-frequency component can be used. For example, instead of a bandpass filter, a high-pass filter having a cutoff frequency of 4000 Hz may be used for filtering. The component extractor 124 may also be omitted and its function may be provided in a different functional block, if the function can be implemented in the different functional block.

In the first embodiment, the high-frequency signal generator 111 outputs a synthesized high-frequency signal HS with skew added to its frequency characteristic, as described above.

The low-frequency signal generator 10 inputs the converted source signal S from the sampling frequency converter 1, generates a signal having a smaller frequency component than the band-limited frequency, and outputs a synthesized low-frequency signal LS to the additive-combiner 6. The high-frequency unvoiced component generator 12 inputs the converted source signal S from the sampling frequency converter 1, generates a synthesized unvoiced signal US, and outputs this signal to the additive combiner 6. The low-frequency signal generator 10 and the high-frequency unvoiced component generator 12 can use existing art concerning methods of generating the synthesized low-frequency signal LS and the synthesized unvoiced signal US.

The additive combiner 6 inputs the synthesized low-frequency signal LS, synthesized high-frequency signal HS, synthesized unvoiced signal US, and converted source signal S, adds them together, and outputs the result as a band-expanded signal V. When the four signals are added in the additive combiner 6, weighting coefficients may be used in the addition. The designer can specify arbitrary weighting coefficients that optimize the quality of the output audio signal. If a delay occurs when the signals are generated, the additive combiner 6 adds the signals at a timing that allows for the delay.

### (A-3) Effect of the First Embodiment

In the first embodiment, since frequency structure features are added to the synthesized high-frequency signal by the frequency structure estimator and structure adjuster, the frequency structure of human speech can be included in the resultant output speech. The quality of the generated wideband signal can thereby be improved.

### (B) Second Embodiment

An out-of-band signal generator and frequency band expander according to a second embodiment of the invention will be described in detail below with reference to the drawings.

The overall structure of the frequency band expander according to the second embodiment can be expressed by FIG. 2, which was used to describe the first embodiment. In the frequency band expander according to the second embodiment, however, the internal structure of the high-frequency signal generator (reference numeral 411 is used in the second embodiment), especially the internal structure of the high-frequency waveform generator (reference numeral 403 in the second embodiment), differs from the structure in the first embodiment.

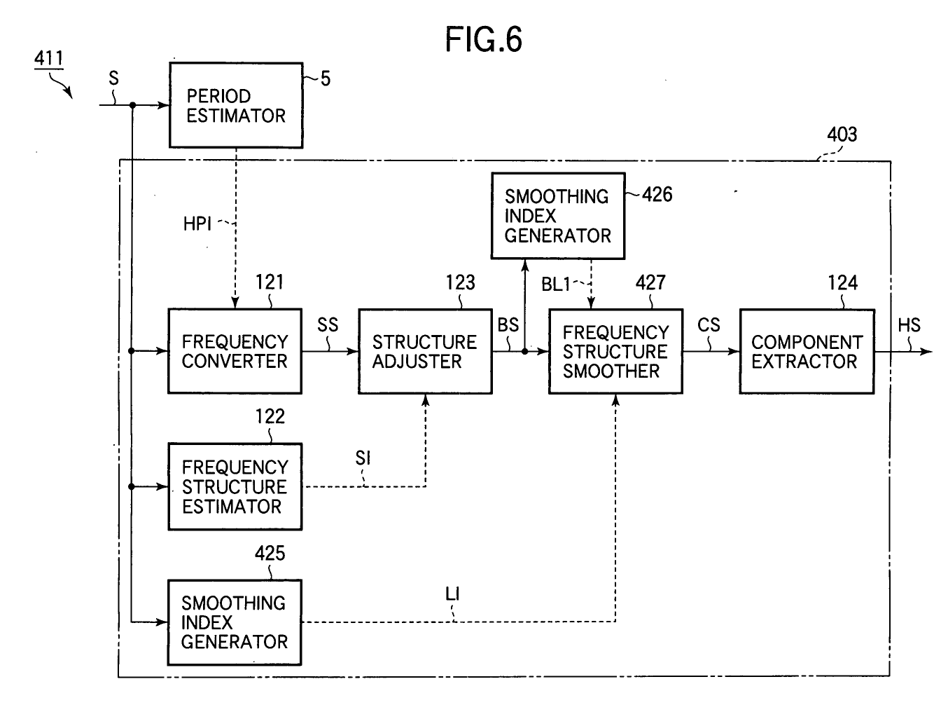

FIG. 6 is a block diagram showing the internal structure of the high-frequency waveform generator 403 in the second embodiment; elements identical to or corresponding to elements shown in FIG. 1 in the first embodiment are given the same reference numerals.

The high-frequency waveform generator 403 of the second embodiment includes first and second smoothing index generators 425, 426 and a frequency structure smoother 427 in addition to a frequency converter 121, frequency structure estimator 122, structure adjuster 123, and component extractor 124.

The first smoothing index generator 425 receives the converted source signal S and outputs smoothing information LI to be used in the frequency structure smoother 427. The method of generating the smoothing information LI will be described later.

The second smoothing index generator 426 receives the modified signal BS and outputs modified smoothing information BLI to be used in the frequency structure smoother 427. The method of generating the smoothing information LI will be described later.

The frequency structure smoother 427 receives the modified signal BS, performs smoothing, which will be described later, on the basis of the smoothing information LI and modified smoothing information BLI, and then outputs a smoothed signal CS.

The operation of the second embodiment, mainly the differences from the first embodiment, will be described below. The second embodiment differs from the first embodiment in the internal operation of the high-frequency signal generator 411.

The first smoothing index generator 425 calculates the strength (power) of a predetermined frequency component in the input converted source signal S and outputs the strength as the smoothing information LI to the frequency structure smoother 427.

Likewise, the second smoothing index generator 426 calculates the strength (power) of the predetermined frequency component in the input modified signal BS and outputs the strength as the modified smoothing information BLI to the frequency structure smoother 427. The predetermined frequency component is, for example, the lowest frequency component of the effective signal generated by the high-frequency signal generator 411; 3400 Hz may be used, but the frequency is not limited to this value.

Based on the smoothing information LI and modified smoothing information BLI, the frequency structure smoother 427 adjusts the power of the input modified signal BS. In the power adjustment process, the power obtained from the smoothing information LI is divided by the power obtained from the modified smoothing information BLI, and amplification is performed with a power gain corresponding to the result. This means that the modified signal BS is adjusted in accordance with the strength of the predetermined frequency component, so that the synthesized high-frequency signal HS generated by the high-frequency signal generator 411 and the converted source signal S, both being input to the additive combiner 6, have a continuous frequency structure. Any method that causes the synthesized high-frequency signal HS and the converted source signal S to have a continuous frequency structure in the additive combiner 6 can be used; the method of smoothing (continuing) the frequency structure is not limited to the method described above.

In addition to the effect of the first embodiment, the second embodiment produces the following effect. Because the generated synthesized high-frequency signal HS and the converted source signal join together so as to have a continuous frequency structure, the quality of the output signal can be improved further.

### (C) Third Embodiment

An out-of-band signal generator and frequency band expander according to a third embodiment of the invention will be described in detail below with reference to the drawings.

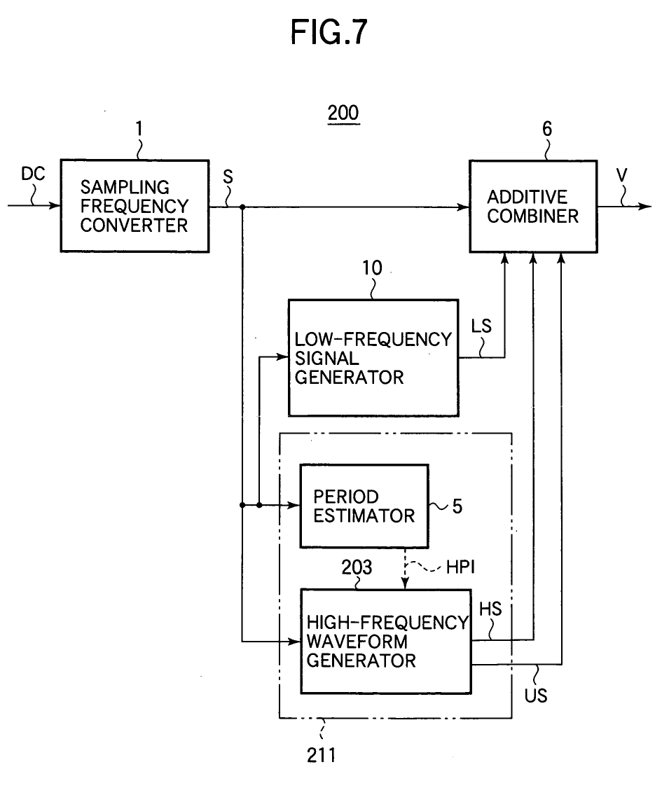

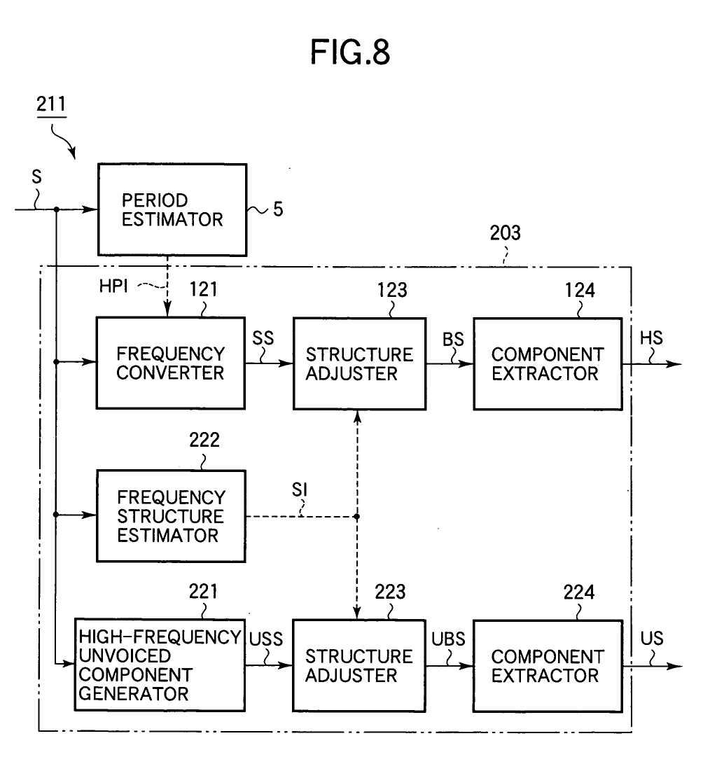

FIG. 7 is a block diagram showing the overall structure of the frequency band expander according to the third embodiment; elements that are identical to or correspond to elements in FIG. 2 in the first embodiment are shown with the same reference numerals. FIG. 8 is a block diagram showing the detailed structure of the high-frequency component signal generator 211; elements in FIG. 8 that are identical to or correspond to elements shown in FIG. 1 in the first embodiment are shown with the same reference numerals.

In FIG. 7, instead of the high-frequency signal generator 111 and high-frequency unvoiced component generator 12 of the first embodiment, the frequency band expander 200 according to the third embodiment includes a high-frequency component signal generator 211 having the detailed structure shown in FIG. 8.

In FIG. 8, the high-frequency component signal generator 211 includes a period estimator 5 and a high-frequency waveform generator 203, and the high-frequency waveform generator 203 includes a frequency converter 121, a high-frequency unvoiced waveform generator 221, a frequency structure estimator 222, structure adjusters 123, 223, and component extractors 124, 224. The frequency converter 121, structure adjuster 123, and component extractor 124 are the same as in the first embodiment.

The high-frequency waveform generator 203 receives the converted source signal S and outputs a synthesized high-frequency signal HS and a synthesized unvoiced signal US in accordance with the fundamental period information HPI.

The frequency structure estimator 222 receives the converted source signal S, estimates the frequency structure of the converted source signal S, and outputs the result as skew information SI. In the third embodiment, the frequency structure estimator 222 also furnishes the skew information SI to the structure adjuster 223 concerned with the high-frequency unvoiced signal.

The high-frequency unvoiced waveform generator 221 receives the converted source signal S and generates an unvoiced waveform source signal USS. As a generation method, an existing method of generating a high-frequency unvoiced waveform may be used.

The structure adjuster 223 receives the unvoiced waveform source signal USS and outputs a modified signal UBS with a skew added in accordance with the skew information SI. The structure adjuster 223 has the same structure as the structure adjuster 123 described in the first embodiment.

The component extractor 224 receives the modified signal UBS and outputs a synthesized unvoiced signal US obtained by component extraction. The component extractor 224 has the same structure as the component extractor 124 described in the first embodiment.

The operation of the third embodiment, mainly the differences from the first and second embodiments, will be described below. The third embodiment differs from the first and second embodiments in the operation of the high-frequency waveform generator 203 in the high-frequency component signal generator 211.

As in the first embodiment, the frequency structure estimator 222 estimates the frequency structure of the input converted source signal S and outputs it as skew information SI. The skew information SI estimated in the third embodiment may approximate the frequency structure as a skew, as in the first embodiment.

The frequency converter 121 carries out a frequency shift of the input converted source signal S by the frequency corresponding to the fundamental period information HPI and outputs a shifted signal SS.

The high-frequency unvoiced waveform generator 221 generates the unvoiced waveform source signal USS, which is a high-frequency unvoiced waveform. The high-frequency unvoiced waveform generator 221 may be identical to the high-frequency unvoiced component generator 12 in the first embodiment and may use a conventional generation method capable of generating a high-frequency unvoiced signal. For example, the unvoiced signal may be generated by passing the output of the frequency converter 121 through a spectral averaging mean filter.

The structure adjusters 123 and 223 impart the skew specified by the skew information SI to the frequency structure of the input shifted signal SS and unvoiced waveform source signal USS, respectively, using the same method as in the first embodiment, and supply the modified signals BS and UBS adjusted frequency structure to the corresponding component extractors 124 and 224. The skew feature to be imparted by the structure adjusters 123 and 223 is determined in advance. In structure adjuster 123, if the skew information SI indicates a positive skew with respect to the input shifted signal SS, for example, filtering is performed by a skewing filter for increasing the skew, and if the skew information SI indicates a negative skew, filtering is performed by a skewing filter for decreasing the skew. Conversely, in the structure adjuster 223, if the skew information SI indicates a positive skew, filtering is performed by a skewing filter for decreasing the skew, and if the skew information SI indicates a negative skew, filtering is performed by a skewing filter for increasing the skew. This can prevent a sudden change from being perceived in the overall volume.

The component extractors 124, 224 perform the same processing as in the first embodiment. Component extractor 224 preferably extracts the same components as the frequency band output from the high-frequency unvoiced component generator 12.

In addition to the effect of the first embodiment, the third embodiment produces the following effect. Because the operations that generate the synthesized unvoiced signal and the synthesized high-frequency signal are combined, a synthesized unvoiced signal and a synthesized high-frequency signal conforming to the input signal can be generated simultaneously, and the two signals can be mutually interrelated. Therefore, the sound quality can be improved further.

### (D) Fourth Embodiment

An out-of-band signal generator and frequency band expander according to a fourth embodiment of the invention will be described in detail below with reference to the drawings.

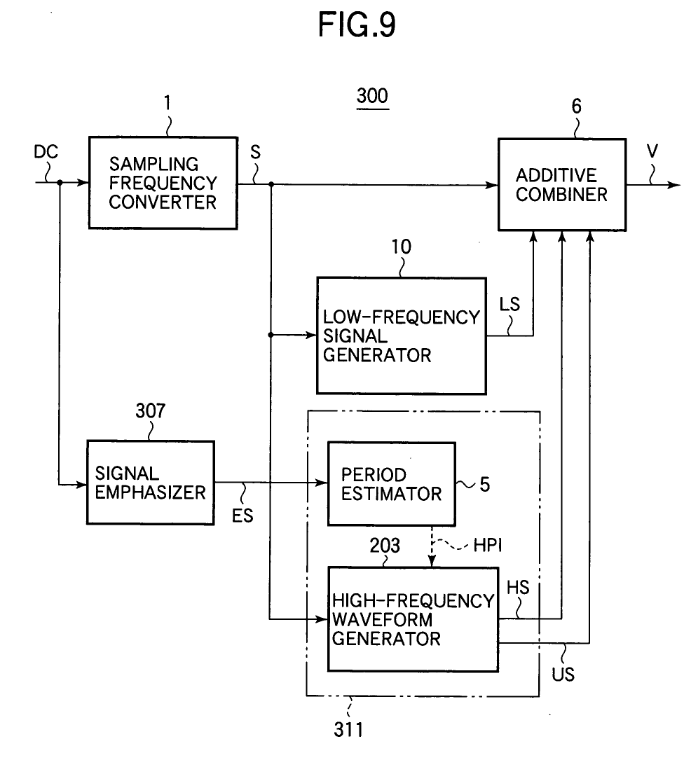

FIG. 9 is a block diagram showing the overall structure of the frequency band expander in the fourth embodiment; elements that are identical to or correspond to elements in FIG. 7 the third embodiment are shown with the same reference numerals.

In FIG. 9, the frequency band expander 300 of the fourth embodiment includes a signal emphasizer 307 in addition to the elements of the third embodiment. The high-frequency component signal generator 311 includes a period estimator 5 and a high-frequency waveform generator 203, as in the third embodiment, but differs from the third embodiment in that the period estimator 5 receives an emphasized signal ES from the signal emphasizer 307.

The signal emphasizer 307 receives the band-limited signal DC, emphasizes a feature included in the band-limited signal DC, and furnishes the emphasized signal ES to the period estimator 5. The process of emphasizing (clarifying) the signal may be any process that improves the accuracy of period estimation if performed before the period estimation by the period estimator 5. For example, a linear prediction coding (LPC) filter may flatten the frequency structure to eliminate features of the frequency envelope. Any process performed to improve the accuracy of period estimation may be used; the process is not limited to the use of an LPC filter.

In addition to the effect of the first embodiment, the fourth embodiment produces the following effect. Because a signal with an emphasized innate feature is input to the period estimating means, its period estimation performance can be enhanced. This can improve the quality of the signal obtained as a result of the frequency shift, consequently improving the quality of the band-expanded signal.

### (E) Variations of the Above Embodiments

The preceding embodiments have been described as generating and combining three types of expanded signals, but the number of types of expanded signals is not limited to three. For example, band expansion may be performed only in the high-frequency band.

The band of the expanded signal is not limited to the band described in the preceding embodiments. For example, an arbitrary frequency band (high frequency band or low frequency band) may be specified, and the resulting band-expanded signal may be wider than the telephone band or may be within the telephone band.

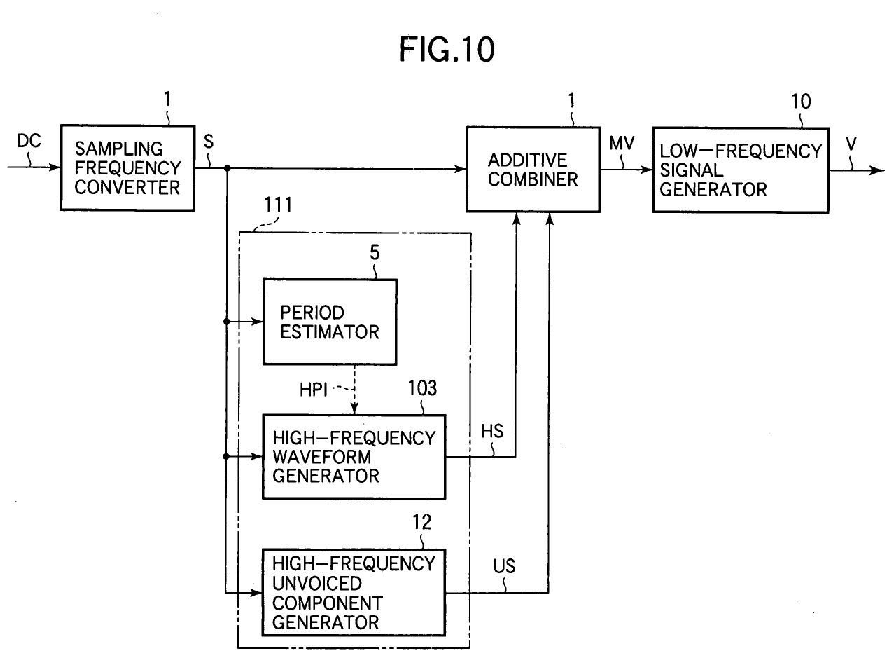

In the preceding embodiments, a plurality of expansion signals are generated in parallel and combined, but the band expansion may be carried out sequentially (serially) on the different components. FIG. 10 shows an exemplary overall structure in which this technique is applied to the technical concept of the first embodiment. In this variation, a band-expanded signal V including a low-frequency signal generated by the low-frequency signal generator 10 is output from a combined signal MV including a high-frequency signal HS and a high-frequency unvoiced signal US.

In the preceding embodiments, the frequency structure of the converted source signal is obtained as a difference between mean levels in two divided bands, and the spectrum of the frequency-shifted signal is skewed. A different structure detection method may be used, however, and the adjustment method may be selected in accordance with the detection method. For example, spectral envelope information may be obtained as the frequency structure of the converted source signal, and the frequency structure of the frequency shifted signal may be adjusted to match an extrapolation of the envelope information.

In the fourth embodiment, the emphasized signal from the signal emphasizer is supplied to the period estimating means, but the signal may also be supplied to another element. For example, the low-frequency signal generator may process the emphasized signal from the signal emphasizer as its input signal. Alternatively, either the converted source signal or the emphasized signal may be selected as the input signal to the low-frequency signal generator.

In the preceding embodiments, the features of the invention are shown as being applied to the generation of a high-frequency signal, but features of the invention may also be used in the generation of a low-frequency signal.

The characteristic technical ideas of the preceding embodiments may be combined arbitrarily to configure a frequency band expander. For example, the fourth embodiment introduces the technical idea of providing a signal emphasizer into the configuration of the third embodiment, but the frequency band expander may be configured by providing a signal emphasizer in the configuration of the first or second embodiment.

The preceding embodiments have been described as processing a voice signal, but the invention can be applied to the band expansion of other periodic signals (such as image signals). The network through which the input signal has passed is not limited to the general public telephone network; it may be an IP network or any other network.

Hardware configurations have been described in the preceding embodiments, but some or all of the processing may be implemented by software.

What is claimed is:

1. An out-of-band signal generator for generating an out-of-band signal from a band-limited signal with a limited frequency band, the out-of-band signal including a frequency component outside the limited frequency band, the out-of-band signal generator comprising:
a frequency structure estimating means for estimating a frequency structure of the band-limited signal;
an out-of-band source signal generating means for generating an out-of-band source signal including an out-of-band frequency component from the band-limited signal;
a frequency structure adjusting means for adjusting the frequency structure of the out-of-band source signal according to the frequency structure of the band-limited signal estimated by the frequency structure estimating means; and
a component extracting means for extracting a prescribed band in the out-of-band source signal with adjusted frequency structure to obtain the out-of-band signal.

2. The out-of-band signal generator of claim 1, further comprising:
a first index generating means for determining a signal strength of the band-limited signal;
a second index generating means for determining a signal strength of the out-of-band source signal; and
a frequency structure smoothing means for adjusting, responsive to results of determinations by the first and second index generating means, the signal strength of the out-of-band source signal output, with its frequency structure adjusted, from the frequency structure adjusting means and furnishing the out-of-band source signal to the component extracting means.

3. The out-of-band signal generator of claim 1, wherein the out-of-band source signal generating means generates the out-of-band source signal by a frequency shift with respect to the band-limited signal.

4. The out-of-band signal generator of claim 3, further comprising a period estimating means for estimating a fundamental period associated with the band-limited signal.

5. The out-of-band signal generator of claim 4, wherein the signal input to the period estimating means is a signal different from the band-limited signal.

6. The out-of-band signal generator of claim 4, wherein the signal input to the period estimating means is a signal in which a feature of the band-limited signal is emphasized.

7. A frequency band expander including an out-of-band signal generator that generates, from a band-limited signal having a limited frequency band, an out-of-band signal including a frequency component outside the limited frequency band, the frequency band expander combining the band-limited signal and the out-of-band signal to obtain a band-expanded signal including a frequency component exceeding a limit of the band-limited signal, wherein:
the out-of-band signal generator recited in claim 1 is used as the out-of-band signal generator.
